(19) United States
(12) Patent Application Publication
(10) Pub. No.: US 2004/0225941 A1
(43) Pub. Date: Nov. 11, 2004

(54) Method of controlling the number of iterations of an iterative decoding process and device for the implementation of the method

(75) Inventor: Arnauld Alain Gerard Taffin, Bures Sur Yvette (FR)

Correspondence Address: Michael L. Kenaga, PIPER RUDNICK LLP, P.O. Box 64807, Chicago, IL, 60664-0807, US

(73) Assignee: NORTEL NETWORKS LIMITED.

(21) Appl. No.: 10/768,259

(22) Filed: Jan. 30, 2004

(30) Foreign Application Priority Data
Feb. 3, 2003 (FR) 03 01191

(51) Int. Cl. H03M 13/00

(52) U.S. Cl. 714/755

(57) ABSTRACT

One controls the number of iterations of a process of iterative decoding of a symbol sequence coded according to a coding scheme using concatenation of convolutional codes in cases of non-convergence. One firstly calculates a quantity related to the convergence of the iterative decoding process, then one compares this quantity with a non-convergence threshold. As a function of this comparison, the iterative decoding process is halted while declaring the sequence undecoded.

### BACKGROUND OF THE INVENTION

The present invention relates to techniques for the iterative decoding of digital data coded according to error correction code concatenation schemes. It applies in particular to iterative decoding methods (“turbo decoding”) for parallel concatenated codes.

The present invention finds application in particular in digital data transmission systems or in digital storage systems.

The studies initiated by Elias (see P. Elias, “Error-free coding”, IRE Trans. On Information Theory, pp. 29-37, 1954) and developed by Formey (see G. D. Formey, “Concatenated codes”, Cambridge, Mass.: MIT res. Monograph no. 37, MIT Press, 1966) conducted with regard to the concatenation of codes, have encouraged the development of iterative decoding procedures that have proved to be particularly well suited to concatenated codes formed by the serial or parallel concatenation of several constituent codes. During the last decade, a family of concatenated codes, consisting of parallel concatenated convolutional codes (PCCC) with interleaving between the codes, commonly referred to as “turbo codes”, has aroused particular interest in the research world and in industry.

In a conventional configuration, a turbo coder consists of a plurality of convolutional coders, typically of recursive systematic convolutional coders (RSC) concatenated in parallel, which may or may not be identical. The binary input data of each constituent coder beyond the first coder are a permuted version of the input data of the first constituent coder, thus outputting redundant parity binary sequences. In addition to the parity binary sequences, the data output by the encoder are identical to the binary input data when systematic constituent coders are used.

In the notation used hereinbelow, n designates the index of the iterations of the iterative decoding process (1≦n≦N_ITE_MAX), k designates the index of the order numbers of the bits of the binary symbol sequences, I designates data output by a permutation operator. This permutation operation is in practice carried out by interleaver modules, to which there correspond deinterleaver modules that carry out the operation inverse to the permutation performed by the interleavers.

FIG. 1 depicts a diagram illustrating a conventional turbo-encoder comprising two RSC constituent coders 10, 11 operating in parallel and an interleaver 12 arranged upstream of the input of the second coder. The sequence of binary random variables representing the information to be coded is denoted \vec{u}=(u¹,u², . . . ,u^{N}). This sequence \vec{u} input to the turbo-coder is applied to the first coder 10 which reproduces them identically at the output, thus constituting a sequence of systematic bits \vec{x}ₛ=(xₛ¹,xₛ², . . . , xₛ^{N}) at the output of the encoder. A permuted version \vec{x}ₛ¹ of the data input to the encoder is applied to the input of the second coder 11 by way of the interleaver 12. The nonsystematic outputs of the coders 10, 11 form the group \vec{x}ₚ¹, \vec{x}ₚ² of sequences of parity bits output by the encoder.

The use of turbo codes is currently envisaged in third-generation cellular networks owing to its superior performance to that of other concatenated codes. For the systems of UMTS (“Universal Mobile Telecommunications System”) type the use of turbo codes for the channel coding of transport channels is described in technical specification 3G TS 25.212, “Multiplexing and channel coding (FDD)—Release 1999”, version 3.9.0, published in December 2001 by the 3GPP.

Various procedures for decoding concatenated codes have been developed. The principle of iterative decoding, particularly well suited to these codes, has in particular been described by S. Gallager for the decoding of LDPC codes (see “Low-Density Parity-Check Codes”, R. Gallager, IRE Trans. On Information Theory, January 1962, and “Low-Density Parity Check Codes”, R. Gallager, M.I.T. Press, Cambridge, Mass.; 1963). The decoder comprising a constituent decoder for each constituent coder of the encoder, the estimate obtained at the output of one constituent decoder is used as input information for another constituent decoder.

The growing success of turbo codes stems from the iterative decoding scheme developed for them. It has subsequently been extended to other concatenated codes, such as serially concatenated convolutional codes (see S. Benedetto, G. Montorsi, S. Divsalar, F. Pollara, “Serial concatenation of interleaved codes: Performance analysis, design and iterative decoding”, TDA Progress report 42-126, JPL, April-June 1996).

FIG. 2 depicts a diagram illustrating a conventional iterative turbo-decoder suitable for the encoder of FIG. 1.

The decoder receives as sequence of binary symbols \vec{y} comprising three groups of symbols \vec{y}ₛ, \vec{y}ₚ¹, \vec{y}ₚ² corresponding respectively to the sequences \vec{x}ₛ, \vec{x}ₚ¹, \vec{x}ₚ² of symbols produced by the encoder. The symbol sequence \vec{y}ₛ corresponding to the systematic bit sequence \vec{x}ₛ is fed to the first constituent decoder 20, while a version \vec{y}ₛ¹ interleaved by an interleaver 22 is fed to the second constituent decoder 21. The sequences \vec{y}ₚ¹,\vec{y}ₚ² corresponding to the parity bits are fed to the first and second constituent decoders, respectively. Each constituent decoder 20, 21 is a with soft input-soft output (SISO) decoder, and produces a sequence of so-called “soft” estimates (decoded symbol estimate sequence, together with reliability measurement information) as well as information derived from these estimates in the form of a pair of sequences \overline{L}¹, \vec{Le}¹ and \vec{L}^{2,I}, \overline{Le}^{2,I} respectively. The decoding algorithm implemented in the decoders 20, 21 may be of MAP (“Maximum A Posteriori”) type or derived type (“max-log-MAP” or “log-MAP” algorithms), or else of Viterbi type with soft outputs (SOVA—“Soft Output Viterbi Algorithm”). A version \vec{Le}^{1,I} interleaved by an interleaver 23 of the sequence \vec{Le}¹ produced by the first decoder 20 is fed to the input of the second decoder 21. A version \vec{Le}² deinterleaved by deinterleaver 24 of the sequence \vec{Le}^{2,I} produced by the second decoder 21 is fed to the input of the first constituent decoder 20.

The quantities (\vec{L}^{j}^{_{—}}^{dec})ⱼ_{dec=1,2} commonly referred to as LLRs (“Log-Likelihood Ratios”), represent the ratio of the a posteriori probabilities of the element u^{k} of the decoded sequence \vec{u} taking one or the other of the possible binary values. They are obtained by the decoders 20,21 according to relation (1)

$${L}^{j\_dec} ( {u}^{k} ) = {log}_{e} [ \frac{Prob ( {u}^{k} = 1 \vert {y}^{->} )}{Prob ( {u}^{k} = 0 \vert {y}^{->} )} ] k = 1 … N \qquad ( 1 )$$

The quantity L^{j}^{dec}(uₖ) represents a weighted estimate because its sign indicates an estimate corresponding to the best decision ûₖ relating to the symbol sent uₖ, while its modulus measures the reliability of this decision.

The sequences (\overline{Le}^{j}^{dec})ⱼ_{dec=1,2} represent a so-called extrinsic information quantity, corresponding to the iterative part transmitted from one decoder to the next. They are exchanged between the decoders 20, 21, so as to be used in each iteration of the decoding process. At iteration n, the quantities (\overline{Le}^{j}^{dec})ⱼ_{dec=1,2} are determined according to relations (2) and (3):

Leₙ¹(ûₙ^{k})=−Leₙ₋₁²(ûₙ^{k})−L_{c}·yₖ+Lₙ¹(ûₙ^{k}) K=1 . . . N (2)

Leₙ^{2,I}(ûₙ^{k})=−Leₙ₋₁^{1,I}(ûₙ^{k})−L_{c}·yₖ+Lₙ^{2,I}(ûₙ^{k}) K=1 . . . N (3)

In equations (2) and (3), the factor L_{c} represents the contribution of an encoded data transmission channel on the received data yₖ.

In practice, it is usual to fix a maximum number of iterations N_ITE_MAX beyond which the iterative decoding process is halted. The value of N_ITE_MAX will depend on the application. It is of the order of 8 in radiocommunication applications for third-generation systems. A control module 23 for the iterative decoding process actuates the constituent decoders 20, 21 so as to produce the results of the decoding and directs the running of the process during the maximum number of iterations envisaged or according to an algorithm for controlling the number of iterations.

A detailed description of iterative decoding algorithms is provided in the article by Hagenauer et al. “Iterative Decoding of Binary Block and Convolutional Codes” (IEEE Transactions on Information Theory, vol. 42, No. 2, March 1996).

Several studies have been conducted with the aim of reducing the number of iterations of the turbo-decoding process that are performed in situations of early convergence. Criteria for stopping the decoding iterations have thus been defined, enabling the iterative decoding process to be halted prematurely when it is considered that the iterations already performed have lead to sufficiently satisfactory estimates. Refer on this subject to the following articles:

“Two Simple Stopping Criteria for Iterative Decoding”, Shao et al., IEEE Transactions on Communications, Volume: 47 Issue: 8 Aug. 1999;

“Reducing average number of turbo decoding iterations”, Shibutani et al., IEE Electronics letters, April 1999, vol. 35, No. 9;

“Increasing throughput of iterative decoders”, Vogt et al., IEE Electronics letters, June 2001, vol. 37, No. 12.

Within the context of implementation of iterative decoding schemes in the field of radiocommunications, and especially when envisaging their use in a radiocommunication terminal, the complexity of such schemes is a parameter that ought to be optimized. The use of calculation resources (signal processor, coprocessor, etc.) is in this regard an energy consuming factor, whose reduction helps to increase the autonomy of a terminal.

An object of the present invention is to optimize the iterative decoding methods.

### SUMMARY OF THE INVENTION

The invention thus proposes a method of controlling the number of iterations of a process of iterative decoding of a symbol sequence coded according to a coding scheme using concatenation of convolutional codes, wherein, for an iteration beyond the first, a quantity related to the convergence of the iterative decoding process is calculated, this quantity is compared with a non-convergence threshold, and the iterative decoding process is stopped as a function of this comparison while declaring the sequence undecoded.

The invention relies on the observation, with a view to taking early action, of the situations of non-convergence of an iterative decoding algorithm. Non-convergence cases are encountered when a sequence to be decoded has been altered by the transmission of the data to such an extent that it would not be usable, even if the maximum number of iterations of the decoding process were to be carried out.

Another aspect of the present invention proposes a device for controlling the number of iterations of an iterative decoding process, comprising means for calculating a quantity related to the convergence of the iterative decoding process, means for comparing this quantity with a no-convergence threshold, and means for stopping the iterative decoding process as a function of this comparison while declaring the sequence undecoded.

Preferably, the means for calculating a quantity related to the convergence of the iterative decoding process will comprise the means for measuring the discrepancy between two estimates of the symbol sequence that are obtained during distinct iterations of the decoding process, these means typically being devised to measure said discrepancy according to a Hamming distance.

The invention is also concerned with a computer program, loadable into a memory associated with a processor, and comprising code portions for implementing a method as defined above during the execution of said program by the processor, as well as to a computer-readable medium on which such a program is recorded.

The invention may be advantageously implemented together with criteria for stopping the decoding based on anticipated convergence, such as those described in the articles mentioned above.

### BRIEF DESCRIPTION THE DRAWINGS

FIG. 1 is a diagram of a conventional turbo encoder.

FIG. 2 is a diagram of a conventional turbo decoder to which the invention may be applied.

FIG. 3 is a flow chart illustrating the method according to the invention in a first embodiment.

FIG. 4 is a flow chart illustrating the method according to the invention in a second embodiment.

FIG. 5 is a diagram illustrating a device according to the invention.

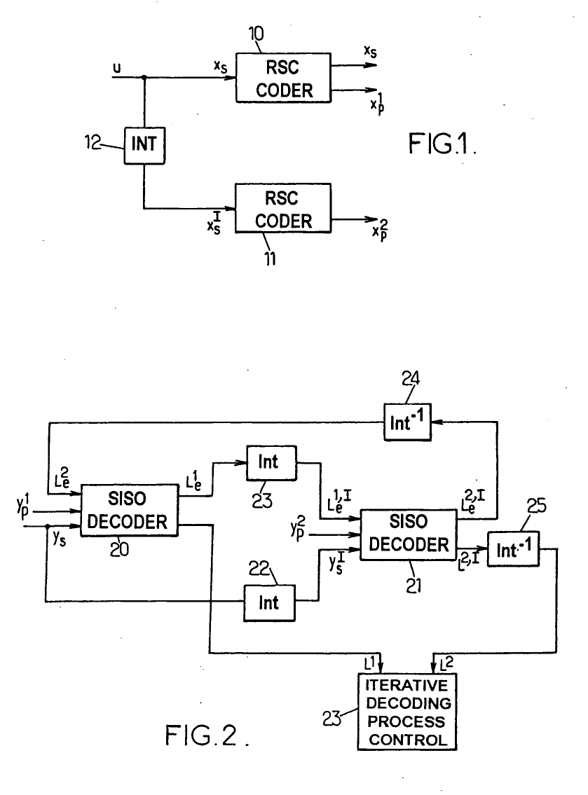

### DESCRIPTION OF PREFERRED EMBODIMENTS

The invention is described below in its non-limiting application to a turbo decoder.

According to the invention, one calculates an estimate of each symbol of the sequence to be decoded during an iteration n of the decoding process, with n≧1. In a preferred embodiment of the invention, this so-called “hard” estimate is obtained by determining the sign of the LLR quantities Lₙ² obtained after the interleaving on the basis of the output Lₙ^{2,I} of the second constituent decoder submitted to the deinterleaver 25.

In another step according to the invention, a quantity related to the convergence of the iterative decoding process is calculated. Preferably, this quantity measures the discrepancy between two estimates of the symbol sequence that are obtained during distinct iterations of the decoding process. Advantageously, this discrepancy is calculated in the sense of the Hamming distance (number of binary positions which differ between the two sequences).

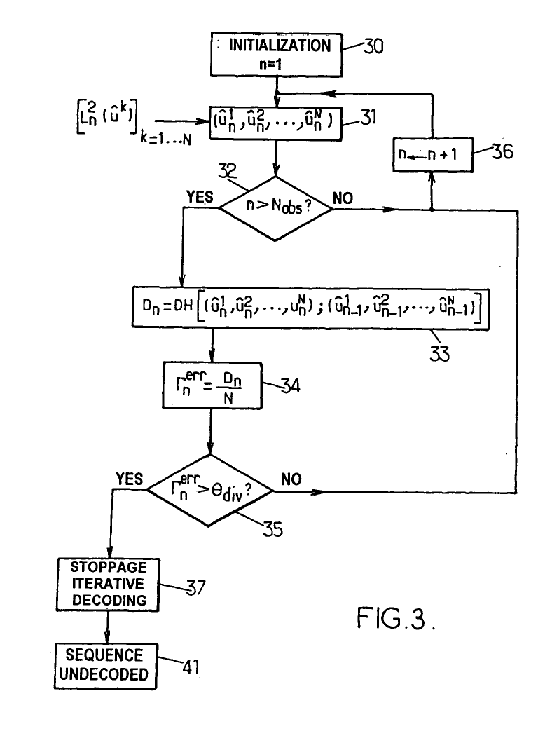

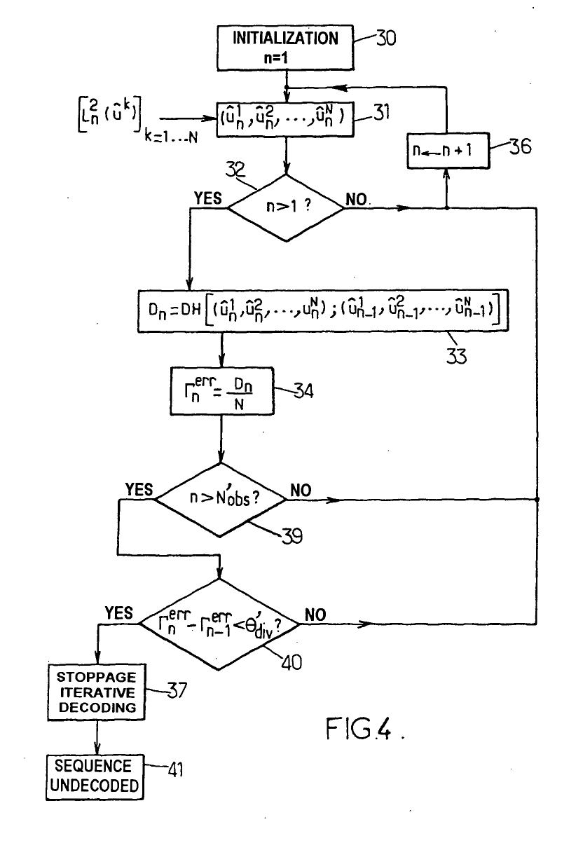

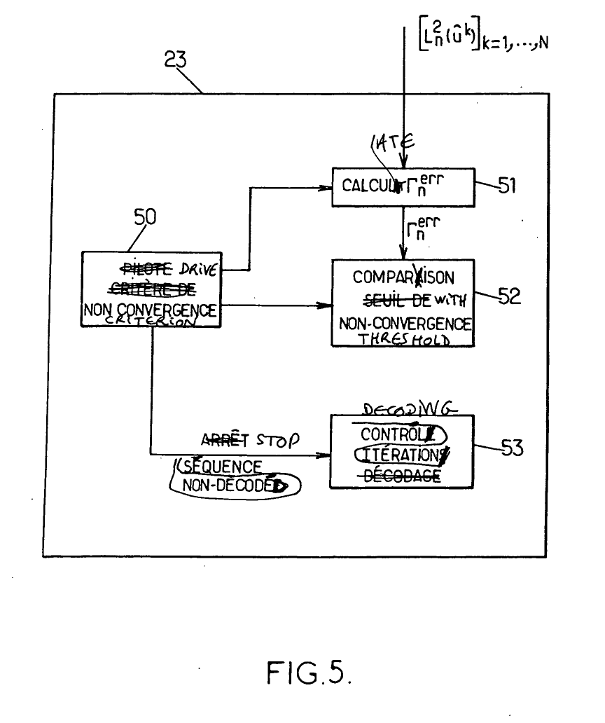

The algorithms depicted in FIGS. 3 and 4 will typically be implemented within the control module 23 described above. This module will therefore be able to drive the succession of iterations of the decoding process having regard to the maximum number envisaged by using a divergence-based stopping criterion according to the invention and possibly a convergence-based stopping criterion.

The algorithm represented in FIG. 3 is initialized with n=1. A loop is executed for the successive values of the index n. Each iteration n in this loop starts with the obtaining 31 of the sequence of estimates ûₙ¹,ûₙ², . . . ,ûₙ^{N} from the quantities L²(u^{k}) whose sign is determined. Step 31 is thus executed in a manner co-ordinated with the iterative decoding process whose execution provides the quantities L²(u^{k}). The sequences of estimates thus obtained are then stored. A test 32 is performed to distinguish the processing carried out during the first few iterations, limited to the obtaining of the sequence and its storage in the previous step. The number of loop iterations for which this limited processing is carried out is determined by the parameter N_{obs}, chosen to be greater than or equal to 1. A setting of N_{obs} beyond 1 enables the decoding stop criterion to be applied only after a determined number of decoding iterations, thus offering a further degree of flexibility of the method according to the invention. If the iteration in progress is beyond the predetermined number N_{obs}, one obtains (33) the Hamming distance Dₙ between the sequence of estimates ûₙ¹,ûₙ², . . . ,ûₙ^{N} obtained in the previous step 31 and the sequence of estimates ûₙ₋₁¹,ûₙ₋₁², . . . ,ûₙ₋₁^{N} obtained in step 31 during the previous iteration. Alternatively, it is possible to calculate the discrepancy between the current sequence of estimates ûₙ¹,ûₙ², . . . ,ûₙ^{N} and the sequence of estimates ûₙ₋ₚ¹,ûₙ₋ₚ², . . . ,ûₙ₋ₚ^{N} obtained in step 31 during any previous iteration n-p. The quantity Dₙ obtained in step 33 can then be normalized in step 34 by the size N of the decoded sequence so as to obtain the criterion Γₙ^{err} which will be compared with the divergence threshold θ_{div} in the next step 35. The normalization operation makes it possible to establish a criterion independent of the number N of binary symbols in a sequence. It is also possible to establish a mean of the distances Dₙ calculated at each iteration n, and to obtain the criterion Γₙ^{err} without departing from the spirit of the invention. If the value of the criterion Γₙ^{err} exceeds the threshold value θ_{div}, the iterative decoding is halted 37 and the sequence declared undecoded (41).

The output of tests 32 and 35 when the test condition is not fulfilled leads to the incrementation 36 of the decoding iteration index n, before returning to step 31 for the next iteration.

The criterion Γₙ^{err} is related to the convergence of the iterative decoding process. When the iterative decoding algorithm converges, its monotonic variations provide an indication of speed of convergence, the algorithm converging to a unique sequence, this being manifested as a reduction toward zero of the value of Γₙ^{err}. The “turbo” effect is observed in cases of convergence after a few iterations of the decoding loop, and the fast convergence of the decoding algorithm is manifested as the fast reducing of the value of Γₙ^{err}. The situations of divergence may thus be detected quickly by comparing Γₙ^{err} with the threshold θ_{div}. In practice, the choice of θ_{div} may result from a compromise between the risk of loss of performance and the quantity of calculation resources that is saved.

In a second embodiment of the invention, a test of non-convergence, based on observation of the variations of Γₙ^{err} is applied. The non-convergence threshold is estimated on the basis of a measure of the discrepancy between two estimates of the symbol sequence that are obtained during distinct iterations of the decoding process, one at least of which differs from the iterations for which the quantity related to the convergence of the iterative decoding process is calculated. The procedure, illustrated in FIG. 4, is similar to that described above for steps 30 to 34, 36 and 37.

The algorithm represented in FIG. 4 is initialized with n=1. A loop is executed for the successive values of the index n. Each iteration n in this loop starts with the obtaining 31 of the sequence of estimates ûₙ¹,ûₙ², . . . ,ûₙ^{N} from the quantities L²(u^{k}). Step 31 is as before executed in a manner coordinated with the iterative decoding process whose execution provides the quantities L²(u^{k}). The sequences of estimates thus obtained are then stored. A test 38 is performed to distinguish the processing carried out during the first iteration, this being limited to the obtaining of the sequence and its storage in the previous step. If the iteration in progress is beyond the first iteration, one obtains 33 the Hamming distance Dₙ between the sequence of estimates ûₙ¹,ûₙ², . . . ,ûₙ^{N} obtained in the previous step 31 and the sequence of estimates ûₙ₋₁¹,ûₙ₋₁², . . . ,ûₙ₋₁^{N} obtained in step 31 during the previous iteration. Alternatively, it is possible to calculate the distance between the current sequence of estimates ûₙ¹,ûₙ², . . . ,ûₙ^{N} and the sequence of estimates ûₙ₋ₚ¹,ûₙ₋ₚ², . . . ,ûₙ₋ₚ^{N} obtained in step 31 during any previous iteration n-p. The quantity Dₙ obtained in step 33 can then be normalized in step 34 by the size N of the decoded sequence so as to obtain the criterion Γₙ^{err}. A test (39) is then performed to distinguish the processing carried out during the first N′_{obs} iterations beyond the first, in the course of which the stopping test 40 is not performed. The number of loop iterations for which this limited processing is carried out is determined by the parameter N′_{bs}, chosen to be greater than or equal to 2. A setting of N′_{obs} beyond 2 enables the decoding stop criterion to be applied only after a determined number of decoding iterations, thus offering a further degree of flexibility in the method according to the invention. When the condition of test 39 is fulfilled, the discrepancy between the criteria Γₙ^{err} and Γₙ₋₁^{err}, is calculated. Alternatively, it is possible to calculate the discrepancy between the criterion obtained for the iteration in progress and the criterion obtained in step 34 during any previous iteration n-p. The discrepancy Γₙ^{err}−Γₙ₋₁^{err} calculated previously is compared with a threshold θ′_{div} in step 40. If the discrepancy is short of this threshold, a situation of non-convergence is detected, the stopping of the iterative decoding process decided (37) and the sequence declared undecoded (41). This amounts to comparing the quantity related to convergence Γₙ^{err} with a measure of the discrepancy Γₙ₋₁^{err} corrected by the value θ′_{div}.

It is also possible to establish a mean of the distances Γₙ^{err}−Γₙ₋₁^{err} calculated at each iteration n, and to obtain a non-convergence criterion, without departing from the spirit of the invention.

The output of tests 38, 39 and 40 when the test condition is not fulfilled leads to the incrementation 36 of the decoding iteration index n before returning to step 31 for the next iteration.

The non-convergence threshold according to the invention may be rendered adaptive, for example as a function of service (transmission of voice, data according to a specified or unspecified service quality) in radio communication applications, without departing from the scope of the invention.

The device represented in FIG. 5 comprises a control module 50 which drives the implementation of the method according to the invention and actuates in succession a module 51 for calculating a quantity related to the convergence of the iterative decoding process and a module 52 for comparing this quantity with a non-convergence threshold. According to the first and second embodiments described above, the module 51 receives the quantities L²(u^{k}) output from the second constituent decoder 21. The modules 50-52 are integrated with the module 23 for controlling the iterative decoding process described above. When a situation of nonconvergence is detected, and the stopping of the iterative decoding process decided, the module 50 transmits an information item for stopping the decoding while declaring the sequence undecoded to a module 53 for controlling the decoding iterations, likewise integrated with the module 23.

In accordance with the first embodiment described above, the means 52 will be devised to compare the quantity related to convergence with a non-convergence threshold obtained on the basis of a predetermined value, and the means 50 will be devised to stop the iterative decoding process as soon as the quantity related to the convergence of the iterative decoding process is greater than this value.

In accordance with the second embodiment described above, the means 52 will be devised to compare the magnitude related to convergence with a non-convergence threshold estimated on the basis of a measurement of the discrepancy between two estimates of the symbol sequence that are obtained during distinct iterations of the decoding process one at least of which differs from the iterations for which the quantity related to the convergence of the iterative decoding process is calculated. Preferably, they will be devised to compare the quantity related to convergence with a non-convergence threshold obtained on the basis of said discrepancy measurement corrected by a predetermined value.

1. A method controlling a number of iterations of an iterative decoding process applied to a symbol sequence coded according to a coding scheme using concatenation of convolutional codes, the method comprising the following steps for an iteration beyond the first iteration:
\a\ calculating a quantity related to convergence of the iterative decoding process;
\b\ comparing said quantity with a non-convergence threshold; and
\c\ stopping the iterative decoding process as a function of said comparison while declaring the sequence undecoded.

2. The method as claimed in claim 1, wherein the quantity related to the convergence of the iterative decoding process measures a discrepancy between two estimates of the symbol sequence, obtained during distinct iterations of the decoding process.

3. The method as claimed in claim 2, wherein said discrepancy is measured according to a Hamming distance.

4. The method as claimed in claim 1, wherein the non-convergence threshold is obtained on the basis of a predetermined value, and the iterative decoding process is stopped as soon as said quantity related to the convergence of the iterative decoding process is greater than said value.

5. The method as claimed in claim 2, wherein the non-convergence threshold is estimated on the basis of a measurement of the discrepancy between two estimates of the symbol sequence respectively obtained during distinct iterations of the decoding process, one at least of which differs from the iterations for which the quantity related to the convergence of the iterative decoding process is calculated.

6. The method as claimed in claim 5, wherein the non-convergence threshold is obtained on the basis of said discrepancy measurement corrected by a predetermined value.

7. The method as claimed in claim 1, wherein the symbol sequence is coded according to a turbo coding scheme.

8. A device for controlling a number of iterations of an iterative decoding process applied to a symbol sequence coded according to a coding scheme using concatenation of convolutional codes, the device comprising means for calculating a quantity related to convergence of the iterative decoding process, means for comparing said quantity with a non-convergence threshold, and means for stopping the iterative decoding process as a function of said comparison while declaring the sequence undecoded.

9. The device as claimed in claim 8, wherein the means for calculating the quantity related to convergence comprise means for measuring a discrepancy between two estimates of the symbol sequence that are obtained during distinct iterations of the decoding process.

10. The device as claimed in claim 9, wherein the means for measuring the discrepancy between two estimates of the symbol sequence that are obtained during distinct iterations of the decoding process are arranged to measure said discrepancy according to a Hamming distance.

11. The device as claimed in claim 8, wherein the comparison means are arranged to compare the quantity related to convergence with a non-convergence threshold obtained on the basis of a predetermined value, and the means for stopping the iterative decoding process are arranged to stop the iterative decoding process as soon as the quantity related to the convergence of the iterative decoding process is greater than said value.

12. The device as claimed in claim 9, wherein the comparison means are arranged to compare the quantity related to convergence with a non-convergence threshold estimated on the basis of a measurement of the discrepancy between two estimates of the symbol sequence respectively obtained during distinct iterations of the decoding process one at least of which differs from the iterations for which the quantity related to the convergence of the iterative decoding process is calculated.

13. The device as claimed in claim 12, wherein the comparison means are arranged to compare the quantity related to convergence with a non-convergence threshold obtained on the basis of said discrepancy measurement corrected by a predetermined value.

14. The device as claimed in claim 8, wherein the means for stopping the iterative decoding process are arranged for controlling the number of iterations of a process of iterative decoding of a symbol sequence coded according to a turbo coding scheme.

15. A computer program product, loadable into a memory associated with a processor for controlling a number of iterations of an iterative decoding process applied to a symbol sequence coded according to a coding scheme using concatenation of convolutional codes, the computer program product comprising code portions for carrying out the following steps for an iteration beyond the first iteration during the execution of the program by the processor:
\a\ calculating a quantity related to convergence of the iterative decoding process;
\b\ comparing said quantity with a non-convergence threshold; and
\c\ stopping the iterative decoding process as a function of said comparison while declaring the sequence undecoded.

16. The computer program product as claimed in claim 15, wherein the quantity related to the convergence of the iterative decoding process measures a discrepancy between two estimates of the symbol sequence, obtained during distinct iterations of the decoding process.

17. The computer program product as claimed in claim 16, wherein said discrepancy is measured according to a Hamming distance.

18. The computer program product as claimed in claim 15, further comprising instructions for obtaining the non-convergence threshold on the basis of a predetermined value, and instructions for stopping the iterative decoding process as soon as said quantity related to the convergence of the iterative decoding process is greater than said value.

19. The computer program product as claimed in claim 16, further comprising instructions for estimating the non-convergence threshold on the basis of a measurement of the discrepancy between two estimates of the symbol sequence respectively obtained during distinct iterations of the decoding process, one at least of which differs from the iterations for which the quantity related to the convergence of the iterative decoding process is calculated.

20. The method as claimed in claim 19, further comprising instructions for obtaining the non-convergence threshold on the basis of said discrepancy measurement corrected by a predetermined value.
